(19) United States
(12) Patent Application Publication
(10) Pub. No.: US 2025/0020570 A1
(43) Pub. Date: Jan. 16, 2025

(54) PHOTOLITHOGRAPH APPARATUS, METHOD FOR INSPECTING PARTICLES AND SEMICONDUCTOR PROCESS

(71) Applicant: National Tsing Hua University, Hsinchu City (TW)

(72) Inventors: Tsai-Sheng Gau, Hsinchu City (TW); Burn Jeng Lin, Hsinchu City (TW); Po-Hsiung Chen, Hsinchu City (TW); Po-Hsun Lu, Hsinchu City (TW); Meng-Chen Lo, Hsinchu City (TW)

(73) Assignee: National Tsing Hua University, Hsinchu City (TW)

(21) Appl. No.: 18/630,987

(22) Filed: Apr. 9, 2024

(30) Foreign Application Priority Data
Jul. 10, 2023 (TW) 112125654

(51) Int. Cl. G01N 15/1434; G03F 7/00

(52) U.S. Cl. CPC G01N 15/1434; G03F 7/70033; G03F 7/70716; G03F 7/7085

(57) ABSTRACT

A method for inspecting particles is suitable for inspecting particles on a substrate. The method for inspecting the particles includes the following. The substrate is disposed on a stage. An inspection radiation is provided to irradiate on the substrate, in which the inspection radiation is suitable for exciting the particles on the substrate to emit a secondary radiation. Also, the secondary radiation is detected to confirm whether the particles exist on the substrate and positions of the particles are detected.

### CROSS-REFERENCE TO RELATED APPLICATION

This application claims the priority benefit of Taiwan application serial no. 112125654, filed on Jul. 10, 2023. The entirety of the above-mentioned patent application is hereby incorporated by reference herein and made a part of this specification.

### BACKGROUND

### Technical Field

The disclosure relates to a semiconductor process, and particularly relates to a photolithograph apparatus and a method for inspecting particles that can be used in the semiconductor process.

### Description of Related Art

The extreme ultraviolet (EUV) light exposure machine is the most important mass production machine for the semiconductor below 7 nm technology generation. Companies that cannot obtain the machine can hardly engage in the most advanced semiconductor technology research. Although the EUV light exposure machine is a powerful tool for mass production, the machine has production problems, such as light source power and cleanliness. The most important production problem is that the reticle in the EUV light exposure machine currently does not have an effective pellicle to protect the reticle from particle contamination. The traditional pellicle absorbs the EUV light and is not suitable for the EUV light exposure machine. In the existing

EUV light exposure machine, the reticle is often contaminated by falling particles in the vacuum chamber, in which the most important falling particles are Sn particles. Since the light source of the UV exposure machine hits the Sn target through a driving laser to generate an exposure radiation with a wavelength of 13.5 nanometers, and during this exposure radiation generation process, the Sn particles is generated. The Sn particles with a size as small as 20 nanometers fall on the reticle, which not only pollutes the reticle and affects the yield rate of the photolithograph process of the semiconductor wafer.

In the prior art, the inspection of particles on the surface of the reticle tends to use image analysis and comparison to detect the position of the particles. However, if this method of image analysis and comparison is to successfully inspect the Sn particles as small as 20 nanometers, the light source required for inspection will lead to tens of billions of inspection costs. Accordingly, how to inspect the particle contamination on the reticle efficiently without greatly increasing the process cost is one of the urgent problems to be solved in the high-end photolithograph process today.

### SUMMARY

Embodiments of the disclosure provide a photolithograph apparatus, a method for inspecting particles, and a semiconductor process.

An embodiment of the disclosure provides a photolithograph apparatus, which includes an exposure light source, an illuminating device, a reticle stage, a projection system, a wafer stage, and a particle inspector. The exposure light source provides an exposure radiation, and the illuminating device receives the exposure radiation. The exposure radiation transmitted in the illuminating device irradiates on a reticle carried by the reticle stage. The wafer stage is suitable for carrying a semiconductor wafer, and a photoresist layer has been formed on the semiconductor wafer, in which the exposure radiation reflected by the reticle is projected onto the photoresist layer on the semiconductor wafer through the projection system. The particle inspector provides an inspection radiation to irradiate the reticle, in which the inspection radiation is suitable for exciting the particles on the reticle to emit a secondary radiation, and the wavelength of the secondary radiation is different from the wavelengths of the exposure radiation and the inspection radiation.

Another embodiment of the disclosure provides a method for inspecting particles suitable for inspecting the particles on a substrate. The method for inspecting the particles includes the following. The substrate is disposed on a stage. An inspection radiation is provided to irradiate on the substrate, in which the inspection radiation is suitable for exciting the particles on the substrate to emit a secondary radiation. The secondary radiation is detected to confirm whether particles exist on the substrate and positions of the particles are detected.

Another embodiment of the disclosure provides a semiconductor process, which includes the following. An inspection radiation is provided to irradiate on a reticle to inspect whether particles exist on the reticle. Next, the reticle is loaded onto a reticle stage of a photolithograph apparatus, and an exposure radiation is provided to perform a photolithograph process on a photoresist layer on a semiconductor wafer, in which the wavelength of the exposure radiation is shorter than the wavelength of the inspection radiation.

### BRIEF DESCRIPTION OF THE DRAWINGS

FIG. 1 is a schematic diagram of a photolithograph apparatus according to an embodiment of the disclosure.

FIG. 2 is a schematic diagram of a photolithograph apparatus according to another embodiment of the disclosure.

FIG. 3 is a schematic diagram of a particle inspector in the first embodiment of the disclosure.

FIG. 4 is a schematic diagram of a particle inspector in the second embodiment of the disclosure.

FIG. 5 is a schematic diagram of a particle inspector in the third embodiment of the disclosure.

FIG. 6 is a flowchart of a semiconductor process according to an embodiment of the disclosure.

### DESCRIPTION OF THE EMBODIMENTS

Embodiments are listed below and described in detail with the accompanying drawings, but the provided embodiments are not intended to limit the scope of the disclosure. In addition, the drawings are merely for illustration purposes and are not drawn to original scale. In order to facilitate understanding, the same elements will be described with the same reference numerals in the following description. In addition, terms such as “comprising”, “including”, and “having” used in the text are all open terms, which means “including but not limited to”. Furthermore, directional terms mentioned in the text, such as “up” and “down”, are merely used to refer to the directions of the drawings, and are not used to limit the disclosure. In addition, the numbers and shapes mentioned in the description are merely used to specifically illustrate the disclosure to facilitate understanding of the content, rather than to limit the disclosure.

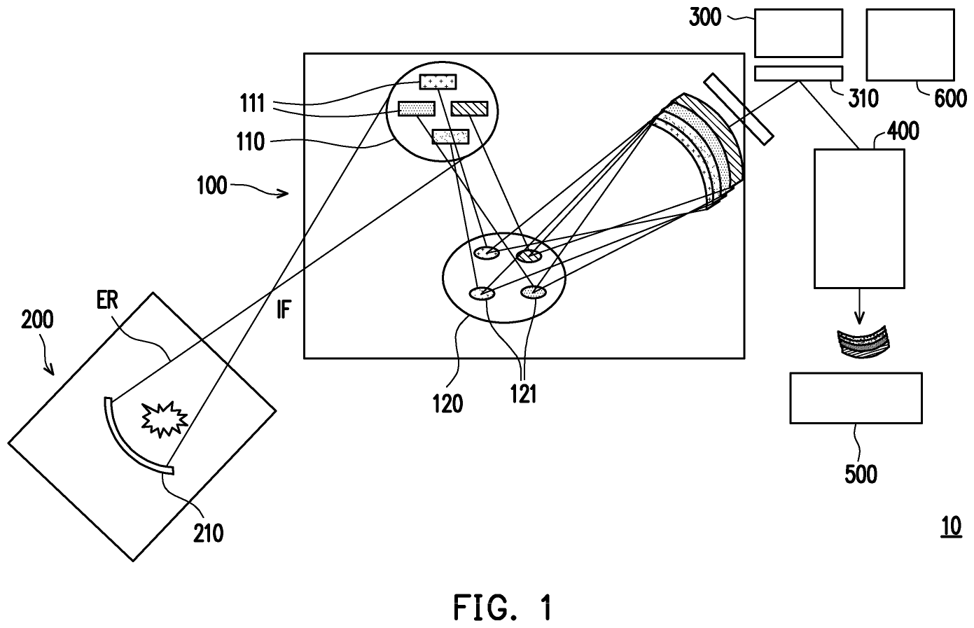

FIG. 1 is a schematic diagram of a photolithograph apparatus according to an embodiment of the disclosure. Referring to FIG. 1. a photolithograph apparatus 10 of this embodiment includes an illuminating device 100, a light source 200, a reticle stage 300, a projection system 400, a wafer stage 500, and a particle inspector 600. The light source 200 is suitable for generating an exposure radiation ER and providing the exposure radiation ER to the illuminating device 100, and the size of the illuminating light beam of the exposure radiation ER may be at micron level. The illuminating device 100 receives the exposure radiation ER from the light source 200 and reflects the exposure radiation ER to a reticle 310 carried by the reticle stage 300. The exposure radiation ER transmitted toward the reticle stage 300 is reflected by the reticle 310 carried by the reticle stage 300 and projected onto a target substrate carried by the wafer stage 500 through the projection system 400. The reticle 310 is suitable for being transmitted between the reticle stage 300 and the particle inspector 600 so that the particle inspector 600 can detect whether particles exist on the reticle 310. The particle inspector 600 is suitable for accommodating the reticle 310 and providing an inspection radiation to irradiate on the reticle 310, in which the inspection radiation is suitable for exciting the particles on the reticle 310 to emit a secondary radiation. In addition, the particle inspector 600 is suitable for detecting the secondary radiation to confirm whether particles exist on the reticle 310. For example, the wavelength of the inspection radiation is in a range from 240 nm to 260 nm, such as 250 nm, and the wavelength of the secondary radiation is in a range from 270 nm to 290 nm, such as 280 nm.

In this embodiment, the light source 200 is an EUV light source. The light source 200 includes an illuminator 210, and the exposure radiation ER generated by the light source 200 is an EUV radiation beam within an EUV wavelength range below 50 nm and having a high energy density. For example, the wavelength of the exposure radiation ER is less than 15 nm or approximately equal to 13.5 nm. Therefore, the light source 200 is a laser-produced plasma (LPP) light source which may be configured to generate the LPP. In the LPP light source, a carbon dioxide laser beam or other suitable excitation laser beam may be provided, and the excitation laser beam is focused on molten Sn droplets to irradiate and excite the molten Sn droplets to generate the LPP. When the molten Sn droplets are irradiated and excited by the excitation laser beam, ions and EUV radiation are generated. In some embodiments, the light source 200 may include a droplet generator and a droplet catcher, and droplets (e.g., the Sn droplets) may be provided by the droplet generator and collected by the droplet catcher. The droplets (e.g., the Sn droplets) provided by the droplet generator may be transmitted from the droplet generator toward the droplet catcher. A part of the droplets transmitted from the droplet generator toward the droplet catcher is irradiated by the excitation laser beam and excited to generate the EUV radiation, while the rest of the droplets transmitted from the droplet generator toward the droplet catcher is not irradiated by the excitation laser beam and is collected by the droplet catcher. The illuminator 210 may be an illuminator mirror configured to focus the EUV radiation of the LPP light source to form the EUV radiation beam. In some embodiments, the illuminator 210 includes a plurality of reflective layers and a plurality of transmissive layers stacked alternately, and each of the reflective layers in the illuminator 210 may be sandwiched between transmissive layers, and each of the reflective layers may reflect the EUV radiation beam emitted from the excitation region respectively. The plurality of reflective layers in the illuminator 210 contribute to the overall reflection of the illuminator 210. In some embodiments, the illuminator 210 includes a Bragg reflector having the plurality of stacked reflective layers.

The exposure radiation ER generated by the light source 200 is collected at an intermediate focal point IF and provided to the illuminating device 100 through the intermediate focal point IF. The illuminating device 100 may at least include a first facet mirror 110 and a second facet mirror 120. The exposure radiation ER transmitted in the illuminating device 100 may be reflected by the first facet mirror 110 and the second facet mirror 120 sequentially. In some embodiments, besides the first facet mirror 110 and the second facet mirror 120, the illuminating device 100 may further include other optical elements (such as reflective mirrors). The first facet mirror 110 includes a plurality of first facet elements 111 arranged in an array, and the first facet elements 111 reflect the exposure radiation ER to the second facet mirror 120. The second facet mirror 120 includes a plurality of second facet elements 121 arranged in an array. In some embodiments, each of the first facet element 111 among the first facet elements 111 may reflect the exposure radiation ER to at least one second facet element 121 among the second facet elements 121 respectively. In some other embodiments, the plurality of first facet elements 111 among the first facet elements 111 may reflect the exposure radiation ER to the same second facet element 121 among the second facet elements 121. In the illuminating device 100, the corresponding relationship between the first facet element 111 and the second facet element 121 may be modified moderately according to design requirements. That is to say, based on the principle of fly's eye, the exposure radiation ER may be projected to different spaces and the angle distribution of the exposure radiation ER may be controlled through the first facet mirror 110 (also referred to as a field facet mirror) and the second facet mirror 120 (also referred to as a pupil facet mirror). The exposure radiation ER may be divided into a plurality of small parts by the first facet mirror 110 including the first facet elements 111. Then, the exposure radiation ER may be uniformly projected by the second facet mirror 120 including the second facet elements 121. Each of the first facet elements 111 may be a mirror, and each of the second facet elements 121 may also be a mirror. Each of the first facet elements 111 in the first facet mirror 110 may rotate individually, thereby controlling the intensity and the angle distribution of the exposure radiation ER reflected by the first facet mirror 110.

Although only four of the first facet elements 111 of the first facet mirror surface 110 and four of the second facet elements 121 of the second facet mirror 120 are shown in FIG. 1, the numbers of the first facet elements 111 included in the first facet mirror 110 and the second facet elements 121 included in the second facet mirror 120 may be more than four. The numbers of the first facet elements 111 and the second facet elements 121 are not limited in the disclosure. The exposure radiation ER is reflected by the first facet elements 111 of the first facet mirror 110 in order to be divided into a plurality of parts. Next, the plurality of parts of the exposure radiation ER are transmitted to the second facet elements 121 of the second facet mirror 120 respectively, and then reflected by the second facet elements 121 to form a radiation beam. Here, the radiation beam is the exposure radiation ER after being reflected by the second facet mirror 120 and may be referred to as a slit pattern.

The exposure radiation ER reflected by the second facet mirror 120 irradiates on the reticle 310 carried by the reticle stage 300 and is reflected by the reticle 310. The reticle 310 may be a multi-layer reflective film having a predetermined pattern, and the predetermined pattern is a pattern to be transferred to a photoresist layer on a semiconductor wafer. The exposure radiation ER reflected by the reticle 310 is projected onto the photoresist layer on the semiconductor wafer (not shown) carried by the wafer stage 500 through the projection system 400, so that the pattern of the reticle 310 may be projected and transferred onto the photoresist layer on the semiconductor wafer carried by the wafer stage 500. After the pattern of the reticle 310 is projected and transferred onto the photoresist layer on the semiconductor wafer carried by the wafer stage 500, the semiconductor wafer may be further processed. For example, developing, hard baking, plating, etching, a combination of the above, or other similar processes may be performed on the semiconductor wafer on which the patterned photoresist layer is formed.

In the photolithograph apparatus 10, since the EUV radiation is generated by focusing the carbon dioxide laser beam on the molten Sn droplets, fine tin particles generated during the process of generating the EUV radiation may be deposited on the reticle 310, causing contamination of the reticle 310. The size of the fine tin particles is usually as small as approximately 20 nanometers. If the inspection of this pollution source is carried out by means of image comparison, a considerable inspection cost is inevitably consumed. Based on the above, the embodiment of the disclosure proposes an inspection method. Through a light source with a wavelength different from the EUV radiation irradiating and exciting the tin particles on the reticle 310, the tin particles emit a fluorescence of a specific wavelength after being excited. The fluorescence of the specific wavelength is captured by the inspector to inspect whether the reticle 310 is contaminated by the tin particles.

The particle inspector 600 may adopt an off-line design. In other words, the particle inspector 600 and the reticle stage 300 may be units independent from each other, and the reticle 310 to be inspected may be transmitted between the particle inspector 600 and the reticle stage 300. In some embodiments, the particle inspector 600 is disposed in the photolithograph apparatus 10, and the disposed position of the particle inspector 600 is not limited to be adjacent to the reticle stage 300, so that there are multiple options for the disposed position of the particle inspector 600. In other embodiments, the particle inspector 600 is positioned outside the photolithograph apparatus 10.

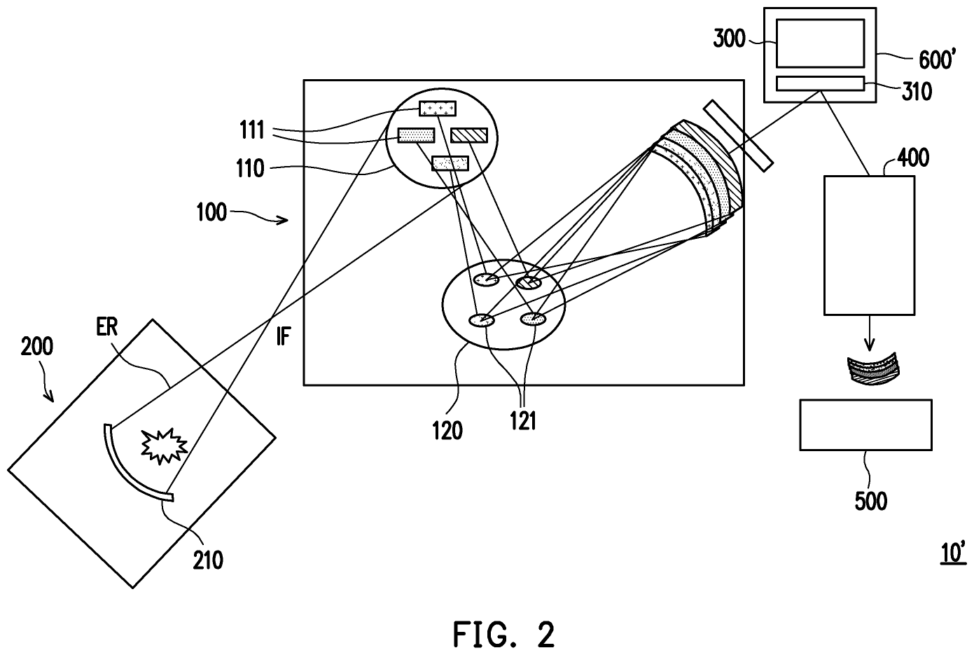

FIG. 2 is a schematic diagram of a photolithograph apparatus according to another embodiment of the disclosure. Referring to FIG. 2, a photolithograph apparatus 10′ of this embodiment includes the illuminating device 100, the light source 200, the reticle stage 300, the projection system 400, the wafer stage 500, and a particle inspector 600′. The light source 200 is suitable for generating the exposure radiation ER and providing the exposure radiation ER to the illuminating device 100. The illuminating device 100 receives the exposure radiation ER from the light source 200 and reflects the exposure radiation ER to the reticle 310 carried by the reticle stage 300. The exposure radiation ER transmitted toward the reticle stage 300 is reflected by the reticle 310 carried by the reticle stage 300 and projected onto a target substrate carried by the wafer stage 500 through the projection system 400. The particle inspector 600′ is suitable for providing the inspection radiation to irradiate the reticle 310 carried by the reticle stage 300, in which the inspection radiation is suitable for exciting the particles on the reticle 310 carried by the reticle stage 300 to emit the secondary radiation. In addition, the particle inspector 600′ is suitable for inspecting the secondary radiation to confirm whether particles exist on the reticle 310. For example, the wavelength of the inspection radiation is in a range from 240 nm to 260 nm, and the wavelength of the secondary radiation is in a range from 270 nm to 290 nm.

The particle inspector 600′ may adopt an in-line design. In other words, the particle inspector 600′ is disposed adjacent to the reticle stage 300, and the particle inspector 600′ is integrated in the reticle stage 300. In the in-line design particle inspector 600′, the reticle 310 to be inspected does not need to be transmitted between the particle inspector 600′ and the reticle stage 300, and the particle inspector 600′ may directly detect whether particles exist on the reticle 310 on the reticle stage 300.

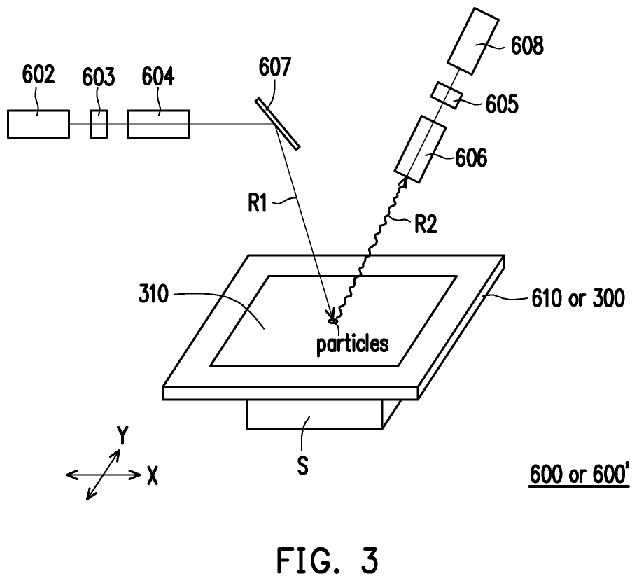

The main difference between the off-line designed particle inspector 600 designed and the in-line designed particle inspector 600′ is that, the off-line designed particle inspector 600 has a reticle stage for inspection 610 (shown in FIG. 3 to FIG. 5), and the in-line designed particle inspector 600′ uses the reticle stage 300 in the photolithograph apparatus 10 directly. In other words, except for the difference between the reticle stage 300 and the reticle stage for inspection 610 (shown in FIG. 3 to FIG. 5), the optical structure of the off-line designed particle inspector 600 and the in-line designed particle inspector 600′ may be the same. The optical structures of the off-line designed particle inspector 600 and the in-line designed particle inspector 600′ will be described below with reference to FIG. 3 to FIG. 5.

FIG. 3 is a schematic diagram of a particle inspector in the first embodiment of the disclosure. Please refer to FIG. 3, the off-line designed particle inspector 600 or the in-line designed particle inspector 600′ includes an inspection light source 602 providing an inspection radiation R1, a first spectrometer 604, a second spectrometer 606, and a detector 608, in which the inspection radiation R1 provided by the inspection light source 602 irradiates on the surface of the reticle 310 through the first spectrometer 604. When particles exist on the reticle 310, the inspection radiation R1 excites the particles on the reticle 310 to emit a secondary radiation R2, and the detector 608 detects the secondary radiation R2 through the second spectrometer 606. In this embodiment, the particle inspector 600 or the particle inspector 600′ further includes a first condense mirror 603 and a second condense mirror 605, in which the inspection radiation R1 irradiates on the surface of the reticle 310 through the first condense mirror 603 and the first spectrometer 604. When particles exist on the reticle 310, the inspection radiation R1 excites the particles on the reticle 310 to emit the secondary radiation R2, and the detector 608 detects the secondary radiation R2 through the second spectrometer 606 and the second condense mirror 605.

In some embodiments, the particle inspector 600 or the particle inspector 600′ further includes a reflector or a beam splitter 607, and the beam splitter 607 is disposed on the optical path between the first spectrometer 604 and the reticle 310, in which the inspection radiation R1 irradiates on the surface of the reticle 310 through the first condense mirror 603, the first spectrometer 604, and the beam splitter 607. When particles exist on the reticle 310, the inspection radiation R1 excites the particles on the reticle 310 to emit the secondary radiation R2, and the detector 608 collects and detects the secondary radiation R2 through the second spectrometer 606 and the second condense mirror 605.

In some embodiments, the off-line designed particle inspector 600 may include a reticle stage for inspection 610 independent of the reticle stage 300, in which the reticle stage for inspection 610 has a scanning mechanism S, and the scanning mechanism S is suitable for driving the reticle 310 to move relative to the inspection radiation R1 (for example, to move on an X-Y plane), so that the inspection radiation R1 scans the surface of the reticle 310.

In some other embodiments, the in-line designed particle inspector 600′ cooperates with the reticle stage 300, and the in-line designed particle inspector 600′ is disposed adjacent to the reticle stage 300, in which the reticle stage 300 has the scanning mechanism S, and the scanning mechanism S is suitable for driving the reticle 310 to move relative to the inspection radiation R1 (for example, to move on the X-Y plane), so that the inspection radiation R1 scans the surface of the reticle 310.

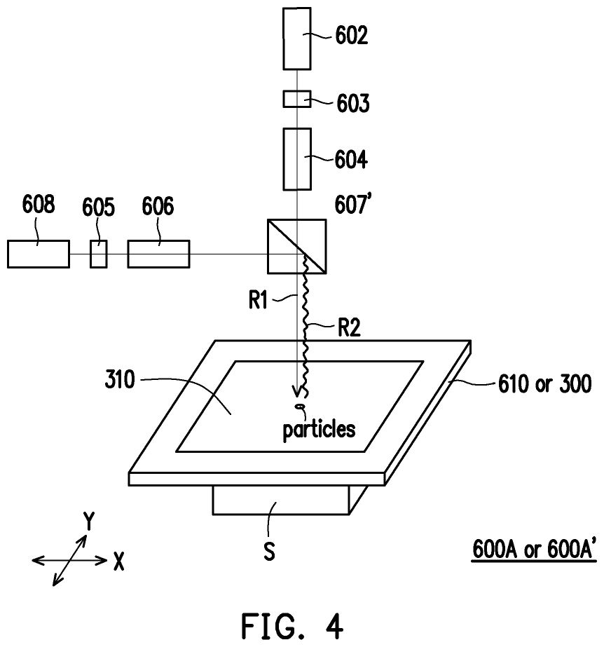

FIG. 4 is a schematic diagram of a particle inspector in the second embodiment of the disclosure. Please refer to FIG. 4. An off-line designed particle inspector 600A or an in-line designed particle inspector 600A′ of this embodiment includes the inspection light source 602 providing the inspection radiation R1, the first condense mirror 603, the first spectrometer 604. the second condense mirror 605, the second spectrometer 606, the beam splitter 607, and the detector 608, in which the inspection radiation R1 irradiates on the surface of the reticle 310 through the first condense mirror 603, the first spectrometer 604, and the beam splitter 607. When particles exist on the reticle 310, the inspection radiation R1 excites the particles on the reticle 310 to emit the secondary radiation R2, and the detector 608 collects and detects the secondary radiation R2 through the beam splitter 607, the second spectrometer 606, and the second condense mirror 605. As shown in FIG. 4, a beam splitter 607′ allows the inspection radiation R1 to pass through so that the inspection radiation R1 may irradiate on the reticle 310, and the beam splitter 607′ is suitable for reflecting the secondary radiation R2 so that the secondary radiation R2 may be detected by the detector 608 through the second spectrometer 606 and the second condense mirror 605.

In some embodiments, the off-line designed particle inspector 600A may include a reticle stage for inspection 610 independent of the reticle stage 300, in which the reticle stage for inspection 610 has the scanning mechanism S, and the scanning mechanism S is suitable for driving the reticle 310 to move relative to the inspection radiation R1 (for example, to move on the X-Y plane), so that the inspection radiation R1 scans the surface of the reticle 310.

In other embodiments, the in-line designed particle inspector 600A′ cooperates with the reticle stage 300, and the in-line designed particle inspector 600A′ is disposed adjacent to the reticle stage 300, in which the reticle stage 300 has the scanning mechanism S, and the scanning mechanism S is suitable for driving the reticle 310 to move relative to the inspection radiation R1 (for example, to move on the X-Y plane), so that the inspection radiation R1 scans the surface of the reticle 310.

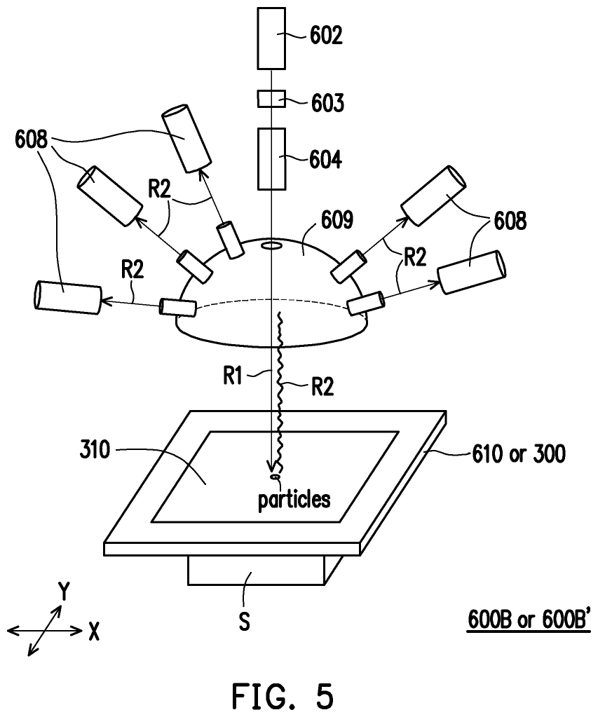

FIG. 5 is a schematic diagram of a particle inspector in the third embodiment of the disclosure. Please refer to FIG. 5. An off-line designed particle inspector 600B or an in-line designed particle inspector 600B′ of this embodiment includes the inspection light source 602 providing the inspection radiation R1, the first condense mirror 603, the spectrometer 604, the plurality of detectors 608 and an optical fiber case 609, in which the inspection radiation R1 irradiates on the surface of the reticle 310 through the condense mirror 603, the spectrometer 604, and the optical fiber case 609. When particles exist on the reticle 310, the inspection radiation R1 excites the particles on the reticle 310 to emit the secondary radiation R2, and the detectors 608 collect and detect the secondary radiation R2 through the optical fiber case 609. As shown in FIG. 5, the optical fiber case 609 allows the inspection radiation R1 to pass through so that the inspection radiation R1 may irradiate on the reticle 310, and the optical fiber case 609 is suitable for collecting the secondary radiation R2 from various angles so that the secondary radiation R2 may be detected by the detector 608. In this embodiment, the optical fiber case 609 has a plurality of optical fibers 609a, and each of the optical fiber 609a points to one of the detectors 608 respectively.

In some embodiments, the offline designed particle inspector 600B may include a reticle stage for inspection 610 independent of the reticle stage 300, the reticle stage for inspection 610 has the scanning mechanism S, and the scanning mechanism S is suitable for driving the reticle 310 to move relative to the inspection radiation R1 (for example, to move on the X-Y plane), so that the inspection radiation R1 scans the surface of the reticle 310.

In some other embodiments, the in-line designed particle inspector 600B′ cooperates with the reticle stage 300, and the in-line designed particle inspector 600B′ is disposed adjacent to the reticle stage 300, in which the reticle stage 300 has the scanning mechanism S, and the scanning mechanism S is suitable for driving the reticle 310 to move relative to the inspection radiation R1 (for example, to move on the X-Y plane), so that the inspection radiation R1 scans the surface of the reticle 310.

It should be noted that, the particle inspectors 600, 600′, 600A, 600A′, 600B, 600B′, and the method for inspecting the particles described in the above embodiments may be used to inspect whether particles exist on the reticle 310, and may also be used to inspect whether particles exist on other types of substrates (such as a semiconductor wafer, a circuit substrate).

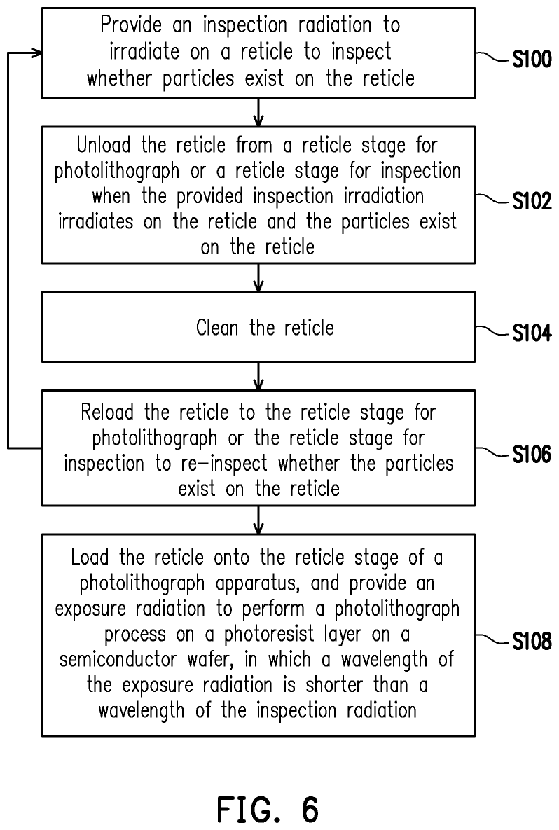

FIG. 6 is a flowchart of a semiconductor process according to an embodiment of the disclosure. Please refer to FIG. 6. The semiconductor process of this embodiment includes the following. First, an inspection radiation is provided to irradiate on a reticle to inspect whether particles exist on the reticle (Step S100). Also, the reticle is loaded onto a reticle stage of a photolithograph apparatus, and an exposure radiation is provided to perform a photolithograph process on a photoresist layer on a semiconductor wafer, in which the wavelength of the exposure radiation is shorter than the wavelength of the inspection radiation (Step S108). In this embodiment, the reticle stage may be a reticle stage for inspection (such as the reticle stage for inspection 610) specially disposed for the inspection purposes, or a reticle stage (such as the reticle stage 300) for carrying the reticle to perform the photolithograph process.

In some embodiments, when the inspection radiation irradiates on the reticle, the reticle is positioned on the reticle stage for photolithograph or the reticle stage for inspection, in which the reticle stage for photolithograph or the reticle stage for inspection drives the reticle to move relative to the inspection radiation, so that the inspection radiation scans the surface of the reticle.

The semiconductor process of this embodiment may further include the following. When the inspection radiation irradiates on the reticle and particles exist on the reticle, the reticle is unloaded from the reticle stage for inspection (S102), the reticle is cleaned (S104), and the reticle is reloaded to the reticle stage for photolithograph or the reticle stage for inspection to re-inspect whether particles exist on the reticle (S106).

In summary, the above-mentioned embodiments of the disclosure can inspect the particle contamination on the reticle efficiently without greatly increasing the process cost. In addition, the position of defects (such as particles) on the reticle can be quickly detected by the scanning mechanism in the reticle stage.

Although the disclosure has been disclosed as above with the embodiments, the embodiments are not intended to limit the disclosure. Persons with ordinary knowledge in the technical field may make some changes and modifications without departing from the spirit and scope of the disclosure. Therefore, the scope of protection of the disclosure should be defined by the scope of the appended claims.

What is claimed is:

1. A photolithograph apparatus, comprising:
an exposure light source providing an exposure radiation;
an illuminating device receiving the exposure radiation;
a reticle stage, wherein the exposure radiation transmitted in the illuminating device irradiates on a reticle carried by the reticle stage;
a projection system:
a wafer stage suitable for carrying a semiconductor wafer, wherein a photoresist layer has been formed on the semiconductor wafer, and the exposure radiation reflected by the reticle is projected onto the photoresist layer on the semiconductor wafer through the projection system; and
a particle inspector providing an inspection radiation to irradiate on the reticle, wherein the inspection radiation is suitable for exciting the particles on the reticle to emit a secondary radiation, and a wavelength of the secondary radiation is different from wavelengths of the exposure radiation and the inspection radiation.

2. The photolithograph apparatus as claimed in claim 1, wherein the exposure radiation comprises an EUV radiation, the particles comprise tin particles, the wavelength of the inspection radiation is in a range from 240 nm to 260 nm, and the wavelength of the secondary radiation is in a range from 270 nm to 290 nm.

3. The photolithograph apparatus as claimed in claim 1, wherein the particle inspector comprises:
an inspection light source providing the inspection radiation;
a first spectrometer;
a second spectrometer; and
a detector, wherein the inspection radiation irradiates on a surface of the reticle through the first spectrometer, when the particles exist on the reticle, the inspection radiation excites the particles on the reticle to emit the secondary radiation, and the detector detects the secondary radiation through the second spectrometer.

4. The photolithograph apparatus as claimed in claim 3, wherein the particle inspector further comprises:
a first condense mirror; and
a second condense mirror, wherein the inspection radiation irradiates on the surface of the reticle through the first condense mirror and the first spectrometer, when the particles exist on the reticle, the inspection radiation excites the particles on the reticle to emit the secondary radiation, and the detector detects the secondary radiation through the second spectrometer and the second condense mirror.

5. The photolithograph apparatus as claimed in claim 3, wherein the particle inspector further comprises:
a beam splitter, wherein the inspection radiation irradiates on the surface of the reticle through the first spectrometer and the beam splitter, when the particles exist on the reticle, the inspection radiation excites the particles on the reticle to emit the secondary radiation, and the detector detects the secondary radiation through the beam splitter and the second spectrometer.

6. The photolithograph apparatus as claimed in claim 1, wherein the particle inspector further comprises:
an inspection light source providing the inspection radiation;
a spectrometer:
an optical fiber case having a plurality of optical fibers; and
a detector, wherein the inspection radiation irradiates on a surface of the reticle through the optical fiber case, when the particles exist on the reticle, the inspection radiation excites the particles on the reticle to emit the secondary radiation, and the detector detects the secondary radiation through the optical fibers.

7. The photolithograph apparatus as claimed in claim 1, wherein the particle inspector further comprises:
a reticle stage for inspection having a scanning mechanism, wherein the scanning mechanism drives the reticle to move relative to the inspection radiation, so that the inspection radiation scans a surface of the reticle.

8. The photolithograph apparatus as claimed in claim 1, wherein the particle inspector is disposed adjacent to the reticle stage, and the reticle stage has a scanning mechanism, and the scanning mechanism drives the reticle to move relative to the inspection radiation, so that the inspection radiation scans a surface of the reticle.

9. A method for inspecting particles suitable for inspecting the particles on a substrate, wherein the method for inspecting the particles comprises:
disposing the substrate on a stage;
providing an inspection radiation to irradiate on the substrate, wherein the inspection radiation is suitable for exciting the particles on the substrate to emit a secondary radiation; and
detecting the secondary radiation to confirm whether the particles exist on the substrate.

10. The method for inspecting the particles as claimed in claim 9, further comprising:
the stage driving the substrate to move relative to the inspection radiation, so that the inspection radiation scans a surface of the substrate.

11. A semiconductor process, comprising:
providing an inspection radiation to irradiate on a reticle to inspect whether particles exist on the reticle; and
loading the reticle onto a reticle stage of a photolithograph apparatus, and an exposure radiation is provided to perform a photolithograph process on a photoresist layer on a semiconductor wafer, wherein a wavelength of the exposure radiation is shorter than a wavelength of the inspection radiation.

12. The semiconductor process as claimed in claim 11, wherein when the provided inspection irradiation irradiates on the reticle, the reticle is positioned on a reticle stage for inspection.

13. The semiconductor process as claimed in claim 12, wherein the reticle stage for inspection drives the reticle to move relative to the inspection radiation, so that the inspection radiation scans a surface of the reticle.

14. The semiconductor process as claimed in claim 12, wherein when the provided inspection irradiation irradiates on the reticle and the particles exist on the reticle, the reticle is unloaded from the reticle stage for inspection, the reticle is cleaned, and the reticle is reloaded to the reticle stage for inspection to re-inspect whether the particles exist on the reticle.

15. The semiconductor process as claimed in claim 11, wherein when the provided inspection radiation irradiates on the reticle, the reticle is positioned on the reticle stage.

16. The semiconductor process as claimed in claim 15, wherein when the provided inspection irradiation irradiates on the reticle and the particles exist on the reticle, the reticle is unloaded from the reticle stage, the reticle is cleaned, and the reticle is reloaded to the reticle stage to re-inspect whether the particles exist on the reticle.

17. The semiconductor process as claimed in claim 15, wherein the reticle stage drives the reticle to move relative to the inspection radiation, so that the inspection radiation scans a surface of the reticle.
